(19) United States
(12) Patent Application Publication
(10) Pub. No.: US 2025/0295019 A1
(43) Pub. Date: Sep. 18, 2025

(54) HEAT DISSIPATION FILM, DISPLAY MODULE AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Wei LIU, Beijing (CN); Xiangdong WEI, Beijing (CN); Jiaming SHEN, Beijing (CN); Xiaodong HAO, Beijing (CN); Wei GONG, Beijing (CN); Yi ZHANG, Beijing (CN); Han ZHANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/860,708

(22) PCT Filed: May 25, 2023
(86) PCT No.: PCT/CN2023/096406

§ 371 Date: Oct. 28, 2024

(30) Foreign Application Priority Data
Jun. 23, 2022 (CN) 202210726247.6

(51) Int. Cl. H10K 59/80

(52) U.S. Cl. CPC H10K 59/8794

(57) ABSTRACT

A heat dissipation film, a display module and a display device, which relate to the technical field of displays. The heat dissipation film includes a foam adhesive layer, and a metal layer, which is laminated on a side of the foam adhesive layer, where an orthographic projection of the metal layer on a plane where the foam adhesive layer is located is located in an area where the foam adhesive layer is located, and at least some of edges of the orthographic projection of the metal layer are located at inner sides of edges of the foam adhesive layer.

### CROSS-REFERENCE TO RELATED APPLICATIONS

The present disclosure is a U.S. National Stage of International Application No. PCT/CN2023/096406, filed on May 25, 2023, which claims priority to Chinese patent application number 202210726247.6 filed on Jun. 23, 2022, entitled “Heat dissipation film, display module and display device”, both of which are incorporated herein by reference in their entireties for all purposes.

### TECHNICAL FIELD

The present disclosure relates to the field of display technology, and in particular to a heat dissipation film, a display module and a display device.

### BACKGROUND

With the acceleration of the upgrading of electronic devices, mobile phones, watches and other electronic devices using OLED (Organic Light Emitting Diode) display substrates as display components are becoming more and more popular. In these electronic devices, the volume of the OLED display substrate is getting smaller and smaller, and the integration and performance requirements are getting higher and higher, which makes the heat generated by the OLED display substrate during operation more and more. At present, the heat dissipation of the OLED display substrate is mainly achieved by attaching a heat dissipation film to the OLED display substrate.

It should be noted that the information disclosed in the above background technology section is only used to enhance the understanding of the background of the present disclosure, and therefore may include information that does not constitute prior art known to those skilled in the art.

### SUMMARY

According to an aspect of the present disclosure, there is provided a heat dissipation film, including:
a foam adhesive layer: and
a metal layer, laminated on a side of the foam adhesive layer, wherein an orthographic projection of the metal layer on a plane where the foam adhesive layer is located is located within a region where the foam adhesive layer is located, and at least part of an edge of the orthographic projection of the metal layer is located inside an edge of the foam adhesive layer.

According to another aspect of the present disclosure, there is provided a display module, including a display substrate and a heat dissipation film according to any one of the above aspects:
the display substrate has a display surface and a non-display surface, and the foam adhesive layer included in the heat dissipation film is attached to the non-display surface of the display substrate.

According to still another aspect of the present disclosure, there is provided a display device, including the display module according to another aspect.

It should be understood that the above general description and the detailed description below are only exemplary and explanatory, and cannot limit the present disclosure.

### BRIEF DESCRIPTION OF THE DRAWINGS

The drawings herein are incorporated into the specification and constitute a part of the specification, showing embodiments consistent with the present disclosure, and are used together with the specification to explain the principles of the present disclosure. Obviously, the drawings described below are only some embodiments of the present disclosure. For those skilled in the art, other drawings can also be obtained based on these drawings without inventive labor.

FIG. 1 is a schematic diagram of a top view structure of a heat dissipation film provided in an embodiment of the present disclosure.

FIG. 2 is a schematic diagram of a cross-sectional structure along A-A′ in FIG. 1.

FIG. 3 is a schematic diagram of a top view structure of a corner of a heat dissipation film provided in an embodiment of the present disclosure.

FIG. 4 is a schematic diagram of a top view structure of a corner of another heat dissipation film provided in an embodiment of the present disclosure.

FIG. 5 is a schematic diagram of a top view structure of another heat dissipation film provided in an embodiment of the present disclosure.

FIG. 6 is a schematic diagram of a cross-sectional structure along A-A′ in FIG. 5.

FIG. 7 is a schematic diagram of a cross-sectional structure of a heat dissipation film provided in an embodiment of the present disclosure.

FIG. 8 is a schematic diagram of a cross-sectional structure of another heat dissipation film provided in an embodiment of the present disclosure.

FIG. 9 is a schematic diagram of a cross-sectional structure of another heat dissipation film provided in an embodiment of the present disclosure.

FIG. 10 is a schematic diagram of a cross-sectional structure of another heat dissipation film provided in an embodiment of the present disclosure.

FIG. 11 is a schematic diagram of a top view structure of a first covering film provided in an embodiment of the present disclosure when it is not peeled off.

FIG. 12 is a schematic diagram of a top view structure of a first covering film provided in an embodiment of the present disclosure after peeling off.

FIG. 13 is a schematic diagram of a cross-sectional structure of another heat dissipation film provided in an embodiment of the present disclosure.

FIG. 14 is a schematic diagram of a cross-sectional structure of another heat dissipation film provided in an embodiment of the present disclosure.

FIG. 15 is a schematic diagram of a top view structure of a corner of another heat dissipation film provided in an embodiment of the present disclosure.

FIG. 16 is a schematic diagram of a top view structure of a corner of another heat dissipation film provided in an embodiment of the present disclosure.

FIG. 17 is a schematic diagram of a top view structure of a corner of another heat dissipation film provided in an embodiment of the present disclosure.

FIG. 18 is a schematic diagram of a structure of a display module provided in an embodiment of the present disclosure.

### REFERENCE NUMERALS

10, heat dissipation film: 20, pixel panel: 30, polarizer: 40, transparent adhesive film: 50, transparent cover plate:
11, foam adhesive layer: 12, metal layer: 13, intermediate laminated layer: 14, release protective film: 15, filling layer;
111, adhesive layer: 112, foam layer;
121, gap: 122, first sub-gap; 123, second sub-gap;
131, first intermediate sub-laminated layer: 132, second intermediate sub-laminated layer:
141, filling film: 142, covering film;
1421, first covering film: 1422, second covering film.

### DETAILED DESCRIPTION

Example embodiments will now be described more fully with reference to the accompanying drawings. However, example embodiments can be implemented in a variety of forms and should not be construed as limited to the embodiments set forth herein; rather, these embodiments are provided so that the present disclosure will be comprehensive and complete and the concepts of the example embodiments will be fully conveyed to those skilled in the art. The same reference numerals in the figures represent the same or similar structures, and their detailed descriptions will be omitted. In addition, the drawings are only schematic illustrations of the present disclosure and are not necessarily drawn to scale.

Although relative terms such as “upper” and “lower” are used in this specification to describe the relative relationship of one component of the icon to another component, these terms are used in this specification only for convenience, for example, according to the directions of the examples described in the drawings. It is understood that if the device of the icon is flipped so that it is upside down, the component described as “upper” will become the component “lower”. When a structure is “on” another structure, it may mean that a structure is formed integrally on the other structure, or that a structure is “directly” set on the other structure, or that a structure is “indirectly” set on the other structure through another structure.

The terms “a”, “an”, “the”, “said” and “at least one” are used to indicate the presence of one or more elements/components/etc.: the terms “including” and “having” are used to indicate an open-ended inclusion and mean that there may be other elements/components/etc. in addition to the listed elements/components/etc.: the terms “first”, “second” and “third” are used only as markers and are not intended to limit the number of objects.

The heat dissipation film 10 generally includes a plurality of laminated layers, and each laminated layer is bonded to ensure the overall effect of the heat dissipation film 10. In the process of manufacturing the heat dissipation film 10, each laminated layer is bonded over a large area and then cut to obtain the heat dissipation film 10 for bonding with the display substrate. During cutting, the feed and withdrawal of the cutter will affect the bonding effect of the edge of the heat dissipation film 10 (i.e., the situation of the separation of some laminated layers at the edge of the heat dissipation film 10), which reduces the yield of the heat dissipation film 10.

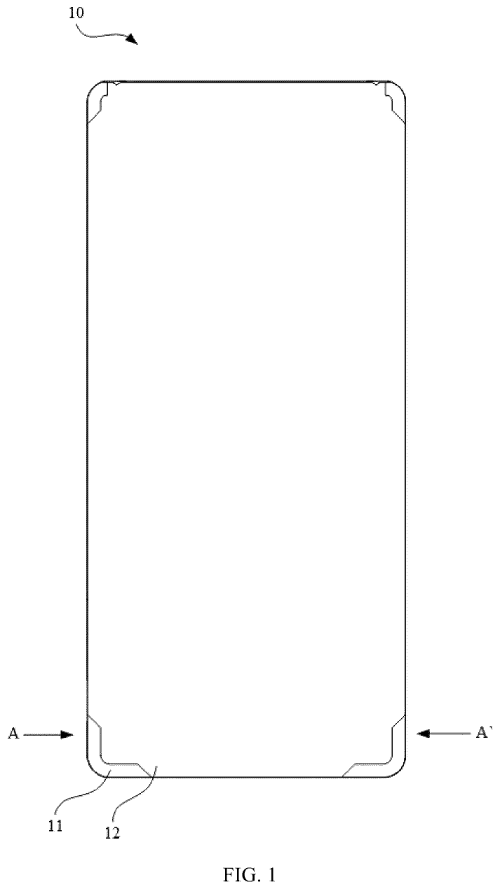

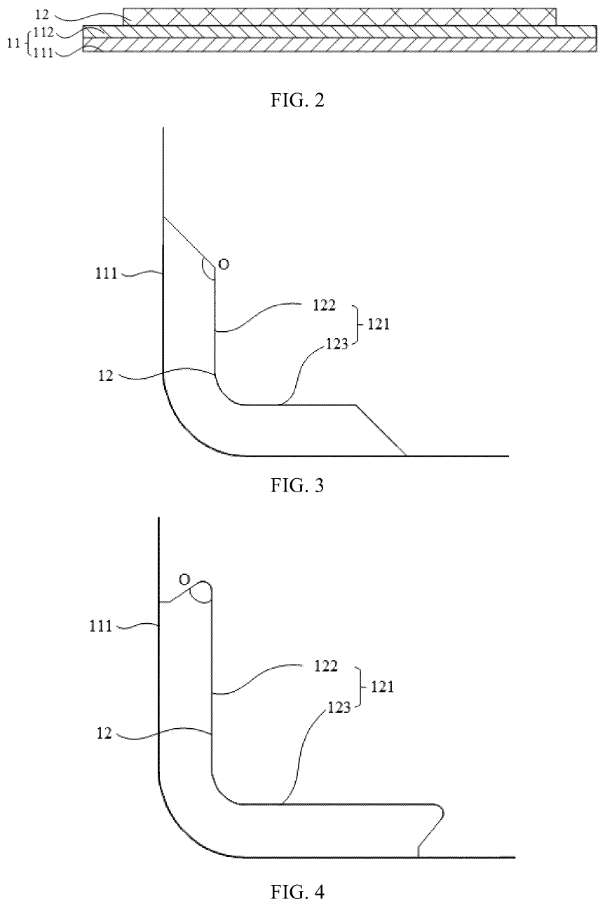

The embodiment of the present disclosure provides a heat dissipation film 10. As shown in FIG. 1 or FIG. 2, the heat dissipation film 10 includes a foam adhesive layer 11 and a metal layer 12. The metal layer 12 is stacked on one side of the foam adhesive layer 11. The orthographic projection of the metal layer 12 on the plane where the foam adhesive layer 11 is located is located within the area where the foam adhesive layer 11 is located, and at least part of the edge of the orthographic projection of the metal layer 12 is located on the inner side of the edge of the foam adhesive layer 11.

Since at least part of the edge of the orthographic projection of the metal layer 12 on the plane where the foam adhesive layer 11 is located is located on the inner side of the edge of the foam adhesive layer 11, that is, the inward design of the metal layer 12 is realized relative to the foam adhesive layer 11, so that when cutting, the influence of the feed and withdrawal of the cutter on the bonding effect of the edge of the heat dissipation film 10 can be reduced, thereby improving the yield of the heat dissipation film 10. In addition, since the influence of the cutter on the edge of the heat dissipation film 10 is avoided, when selecting the material of each laminated layer of the heat dissipation film 10, the restriction of the selection of some laminated layers is avoided as long as each laminated layer can be firmly bonded.

When making the heat dissipation film 10, the large-area metal layer 12 can be cut in advance according to the inward edge and inward amount of the metal layer 12, and then the cut large-area metal layer 12 is bonded to the large-area foam adhesive layer 11, and then the bonded large-area heat dissipation film 10 is cut to obtain the heat dissipation film 10 described in the embodiment of the present disclosure.

The heat dissipation film 10 can be a structure of other shapes such as a rectangular structure and a circular structure. The heat dissipation film 10 is configured to be bonded to the non-display surface of the display substrate through the foam adhesive layer 11. The heat dissipation film 10 is not only used to achieve heat dissipation of the display substrate, but also to improve the strength and electromagnetic shielding performance of the display substrate.

The material of the metal layer 12 can be a metal with good thermal conductivity such as copper. The edge area of the metal layer 12 that is inwardly retracted compared to the foam adhesive layer 11 can be determined according to the specific structure of the heat dissipation film 10 and the area that is easily affected by the cutter during cutting.

For example, the heat dissipation film 10 is a rectangular structure, and the edges of the metal layer 12 that are inwardly retracted can include the edges of the four corners of the metal layer 12 as shown in FIG. 1, that is, the four corners of the metal layer 12 in FIG. 1 all have notches 121. The edges of the metal layer 12 that are inwardly retracted can be arc edges of the corners, that is, the corners of the metal layer 12 have arc notches 121: or they can be L-shaped edges of the corners, that is, the corners of the metal layer 12 have L-shaped notches 121. Of course, the edges of the metal layer 12 that are inwardly retracted can also include the entire edge of the metal layer 12, and the embodiments of the present disclosure are not limited to this, as long as it can avoid affecting the bonding effect of the various laminated layers at the edge of the heat dissipation film 10 during cutting.

Continuing with the example, the heat dissipation film 10 is a circular structure, and the edges of the metal layer 12 that are inwardly retracted can include the entire edge of the metal layer 12.

Taking the corner of the metal layer 12 with an L-shaped notch 121 as an example, as shown in FIG. 3 or FIG. 4, the corner of the metal layer 12 includes a first sub-notch 122 extending in the row direction and a second sub-notch 123 extending in the column direction, and the first end of the first sub-notch 122 is communicated with the first end of the second sub-notch 123. In this way, the inward retracted area of the edge of the metal layer 12 can be increased by extending the first sub-notch 122 and the second sub-notch 123, so that the influence area of the cutter on the edge of the heat dissipation film 10 is further reduced when cutting the heat dissipation film 10, so as to further ensure the yield of the heat dissipation film 10.

The extending length of the first sub-notch 122 and the second sub-notch 123 can be determined according to the structure of the heat dissipation film 10 and the influence area of the cutter on the edge of the heat dissipation film 10 during cutting. The edge of the metal layer 12 at the second end of the first sub-notch 122 and the edge of the metal layer 12 at the second end of the second sub-notch 123 can be a straight-line structure, a sawtooth structure, or an arc structure, which is not limited in the embodiment of the present disclosure. Taking the example that the edge of the metal layer 12 at the second end of the first sub-notch 122 and the edge of the metal layer 12 at the second end of the second sub-gap 123 are both straight line structures, the corner of the edge of the metal layer 12 at the second end of the first sub-notch 122 and the corner of the edge of the metal layer 12 at the second end of the second sub-notch 123 can be an obtuse angle, a right angle or an acute angle. For example, as shown in FIG. 3, the corner O of the edge of the metal layer 12 at the second end of the first sub-notch 122 is an obtuse angle: as shown in FIG. 4, the corner O of the edge of the metal layer 12 at the second end of the first sub-notch 122 is an acute angle.

In addition, the edge structure of the metal layer 12 at the second end of the first sub-notch 122 and the edge structure at the second end of the second sub-notch 123 can be the same or different: and the corner of the edge of the metal layer 12 at the second end of the first sub-notch 122 and the corner of the edge of the metal layer 12 at the second end of the second sub-notch 123 can be the same or different.

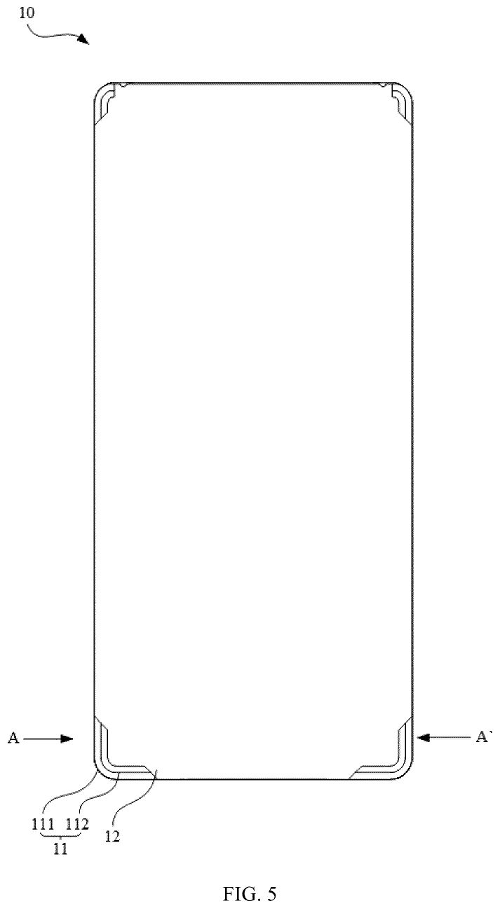

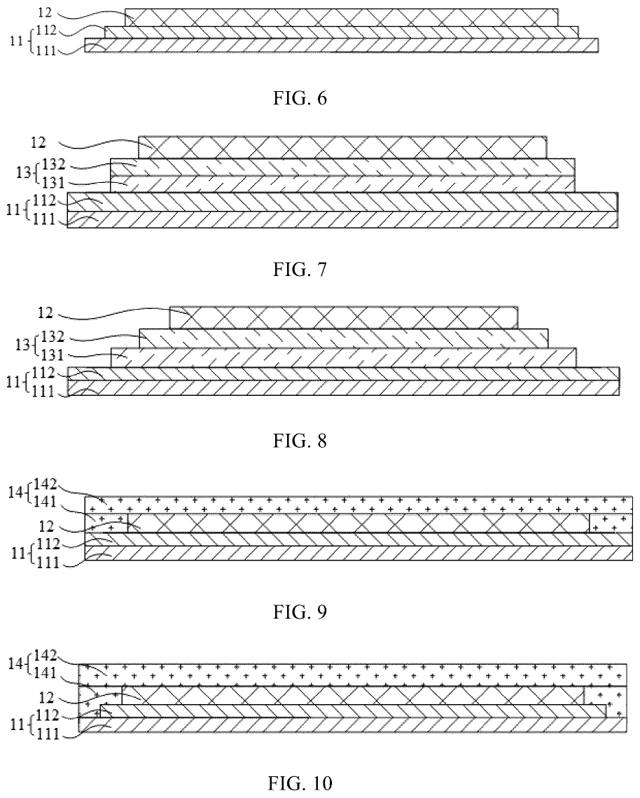

In the embodiment of the present disclosure, as shown in FIG. 1, FIG. 2, FIG. 5 or FIG. 6, the foam adhesive layer 11 includes an adhesive layer 111 and a foam layer 112, and the foam layer 112 is located between the adhesive layer 111 and the metal layer 12.

The adhesive layer 111 and the foam layer 112 can be an integrated structure, and at this time, there will be no separation of laminated layers between the adhesive layer 111 and the foam layer 112. Thus, as shown in FIG. 1 or FIG. 2, the edges of the adhesive layer 111 and the foam layer 112 are aligned. Of course, the adhesive layer 111 and the foam layer 112 can also be bonded to obtain the foam adhesive layer 11. In the case of bonding, there is separation of the laminated layers between the adhesive layer 111 and the foam layer 112. Thus, as shown in FIG. 5 or FIG. 6, the orthographic projection of the foam layer 112 on the plane where the adhesive layer 111 is located is located within the area where the adhesive layer 111 is located, and at least part of the edge of the orthographic projection of the foam layer 112 is located on the inner side of the edge of the adhesive layer 111.

In this way, the inward-retracted design of the foam layer 112 relative to the adhesive layer 111 can be realized, and then when cutting, the influence of the feed and withdrawal of the cutter on the bonding effect of the edge of the heat dissipation film 10 can be reduced, thereby improving the yield of the heat dissipation film 10.

The inward-retracted design of the foam layer 112 relative to the adhesive layer 111 can be specifically referred to the inward-retracted design of the metal layer 12 relative to the foam adhesive layer 11 described in the above embodiment, and such content will not be repeated in the embodiment of the present disclosure. For example, for a rectangular heat dissipation film 10, the foam layer 112 is retracted at four corners relative to the adhesive layer 111.

In addition, the edge of the metal layer 12 can be flush with the edge of the foam layer 112. Alternatively, the orthographic projection of the metal layer 12 on the adhesive layer 111 can also be located within the orthographic projection of the foam layer 112 on the adhesive layer 111, and at least part of the edge of the orthographic projection of the metal layer 12 is located on the inner side of the edge of the orthographic projection of the foam layer 112.

In this way, the metal layer 12 is designed to be inwardly retracted relative to the foam layer 112, and the influence of the feed and withdrawal of the cutter on the bonding effect of the edge of the heat dissipation film 10 is further reduced, thereby improving the yield of the heat dissipation film 10.

The inward retraction design of the metal layer 12 relative to the foam layer 112 can be specifically referred to the inward retraction design of the metal layer 12 relative to the foam adhesive layer 11 described in the above embodiment, and such content will not be repeated in the embodiment of the present disclosure. For example, for a rectangular heat dissipation film 10, the foam layer 112 is inwardly retracted at four corners relative to the adhesive layer 111.

In the embodiment of the present disclosure, in addition to the foam adhesive layer 11 and the metal layer 12, in order to improve the heat dissipation effect of the heat dissipation film 10, as shown in FIG. 7 or FIG. 8, the heat dissipation film 10 also includes an intermediate laminated layer 13, and the intermediate laminated layer 13 is located between the foam adhesive layer 11 and the metal layer 12.

In some embodiments, the edge of the intermediate laminated layer 13 is aligned with the edge of the metal layer 12. In combination with the above-mentioned heat dissipation film 10 including the foam adhesive layer 11 and the metal sheet, since the edge of the intermediate laminated layer 13 is aligned with the edge of the metal layer 12, the design of the intermediate laminated layer 13 will not affect the bonding effect of the edge of the heat dissipation film 10 upon the feed or withdrawal of the cutter.

In other embodiments, as shown in FIG. 7 or FIG. 8, the orthographic projection of the intermediate laminated layer 13 on the plane where the foam adhesive layer 11 is located is located within the foam adhesive layer 11, and at least part of the edge of the orthographic projection of the intermediate laminated layer 13 is located on the inner side of the edge of the foam adhesive layer 11. The orthographic projection of the metal layer 12 on the foam adhesive layer 11 is located within the orthographic projection of the intermediate laminated layer 13 on the foam adhesive layer 11, and at least part of the edge of the orthographic projection of the metal layer 12 is located on the inner side of the edge of the orthographic projection of the intermediate laminated layer 13.

In this way, the inward retraction design of the intermediate laminated layer 13 relative to the foam adhesive layer 11 and the inward retraction design of the metal layer 12 relative to the intermediate laminated layer 13 can be realized, and then when cutting, the influence of the feed and withdrawal of the cutter on the bonding effect of the edge of the heat dissipation film 10 can be reduced, thereby ensuring the yield of the heat dissipation film 10.

The intermediate laminated layer 13 can be a single laminated layer. For example, the intermediate laminated layer 13 can be a graphite layer or an insulating layer. Of course, the intermediate laminated layer 13 can also be multiple laminated layers. For example, the intermediate laminated layer 13 includes a graphite layer and an insulating layer at the same time.

In the case where the intermediate laminated layer 13 is a single laminated layer, the inward retraction design of the intermediate laminated layer 13 relative to the foam adhesive layer 11 can refer to the inward retraction design of the metal layer 12 relative to the foam adhesive layer 11 described in the above embodiment, and such content will not be repeated in the embodiment of the present disclosure.

In the case where the intermediate laminated layer 13 includes multiple laminated layers, in some embodiments, as shown in FIG. 7, the intermediate laminated layer 13 includes multiple intermediate laminated sub-layers, and the edges of the multiple intermediate laminated sub-layers are aligned, that is, there is no inward retraction design between the multiple intermediate laminated sub-layers.

In other embodiments, as shown in FIG. 8, two adjacent intermediate laminated sub-layers include a first intermediate laminated sub-layers 131 close to the metal layer 12, and a second intermediate laminated sub-layers 132 away from the metal layer 12. The orthographic projection of the first intermediate laminated sub-layers 131 on the foam adhesive layer 11 is located within the orthographic projection of the second intermediate laminated sub-layers 132 on the foam adhesive layer 11, and at least part of the edge of the orthographic projection of the first intermediate laminated sub-layers 131 is located inside the edge of the orthographic projection of the second intermediate laminated sub-layers 132.

In this way, the inward-retracted design of the first intermediate laminated sub-layers 131 relative to the second intermediate laminated sub-layers 132 and the inward-retracted design of the metal layer 12 relative to the first intermediate laminated sub-layers 131 can be achieved, and thus when cutting, the influence of the feed and withdrawal of the cutter on the bonding effect of the edge of the heat dissipation film 10 can be reduced, thereby ensuring the yield of the heat dissipation film 10.

In some embodiments, as shown in FIG. 9 or FIG. 10, the heat dissipation film 10 further includes a release protective film 14, and the release protective film 14 includes a filling film 141 and a covering film 142.

Taking the heat dissipation film 10 including a foam adhesive layer 11 and a metal layer 12 as an example, as shown in FIG. 9 or FIG. 10, the filling film 141 is located on the side of the foam adhesive layer 11 close to the metal layer 12, and the orthographic projection of the filling film 141 on the foam adhesive layer 11 is located outside the orthographic projection of the metal layer 12 on the foam adhesive layer 11. The covering film 142 is located on the side of the metal layer 12 away from the foam adhesive layer 11, and the orthographic projection of the filling film 141 on the foam adhesive layer 11 and the orthographic projection of the metal layer 12 on the foam adhesive layer 11 are both located within the orthographic projection of the covering film 142 on the foam adhesive layer 11.

In this way, through the design of the filling film 141 and the covering film 142, not only can the heat dissipation film 10 be protected, but also when the heat dissipation film 10 is pressed onto the display substrate by the roller, the contact area between the roller and the heat dissipation film 10 can be increased, thereby ensuring that the heat dissipation film 10 is adhered to the display substrate, and avoiding false adherence phenomenon in local areas.

The filling film 141 and the covering film 142 are made of the same material. For example, the filling film 141 and the covering film 142 are made of PET. The filling film 141 and the covering film 142 can be of integrated design. Of course, in order to simplify the manufacturing process of the release protective film 14, the filling film 141 and the covering film 142 can also be bonded.

In some embodiments, the filling film 141 covers the area on the foam adhesive layer 11 that is not covered by the metal layer 12. The surface of the filling film 141 away from the foam adhesive layer 11 is flush with the surface of the metal layer 12 away from the foam adhesive layer 11, and the edges of the covering film 142 are all aligned at least with the edges of the foam adhesive layer 11, so as to ensure that the entire area of the heat dissipation film 10 can be rolled when pressed by the roller, and the entire area of the heat dissipation film 10 is evenly stressed.

In addition, after the heat dissipation film 10 is attached to the non-display surface of the display substrate, the covering film 142 and the filling film 141 can be peeled off. In some embodiments, the area corresponding to the filling film 141 after peeling off can be coated with glue to further improve the bonding effect of the edges of each laminated layer of the inward retraction design, thereby extending the service life of the heat dissipation film 10. The operation of coating glue can be specifically explained in the following embodiments.

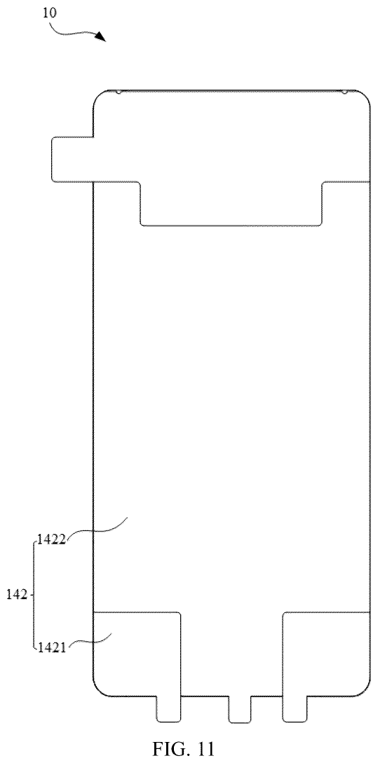

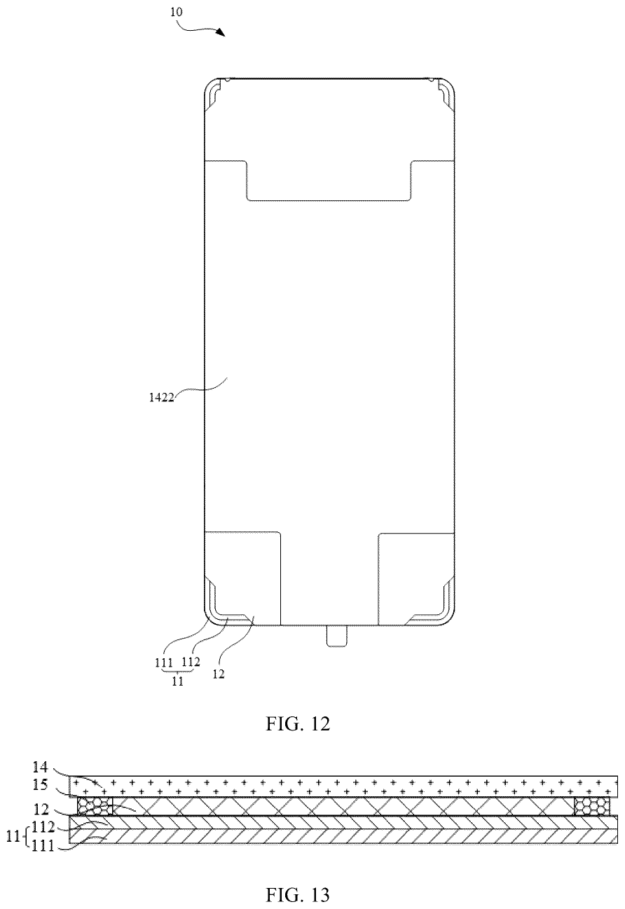

When peeling off the covering film 142, in order to avoid damage to the metal layer 12 caused by an external object after the entire covering film 142 is peeled off, only the area corresponding to the filling film 141 on the covering film 142 can be peeled off. At this time, as shown in FIG. 11 and FIG. 12, the covering film 142 includes a first covering film 1421 and a second covering film 1422. The first covering film 1421 is configured to cover the filling film 141, and the second covering film 1422 is configured to cover the metal layer 12, so that when applying glue to the area corresponding to the filling film 141, it is only necessary to peel off the first covering film 1421 and the filling film 141.

It should be noted that in the case where the heat dissipation film 10 further includes an intermediate laminated layer 13, the structure of the filling film 141 can be adjusted, that is, the filling film 141 simultaneously covers the area on the foam glue layer 11 that is not covered by the intermediate laminated layer 13, and the area on the intermediate laminated layer 13 that is not covered by the metal layer 12. For other structures, please refer to the above description of the embodiment which only includes the foam glue layer 11 and the metal layer 12, and the related content will not be repeated in the embodiments of the present disclosure.

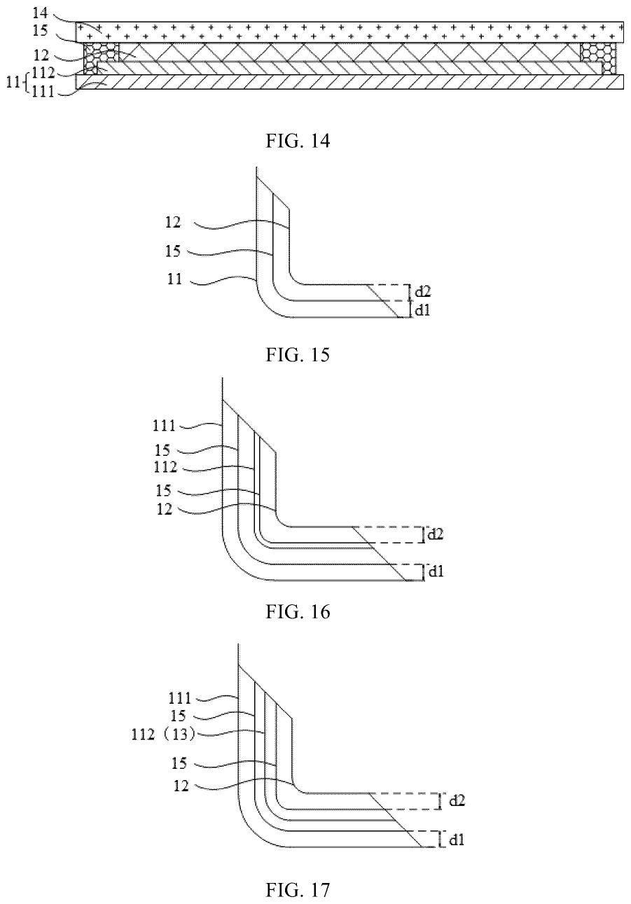

In some embodiments, for the multiple laminated layers included in the heat dissipation film 10, due to the different physical property of each laminated layer, after long-term use, some laminated layers may be separated. In order to further avoid the phenomenon of separation of the laminated layers, as shown in FIG. 13 or FIG. 14, the heat dissipation film 10 further includes a filling layer 15.

Taking the heat dissipation film 10 including a foam adhesive layer 11 and a metal layer 12 as an example, as shown in FIG. 13 or FIG. 14, the filling layer 15 is located on the side of the foam adhesive layer 11 close to the metal layer 12, and the orthographic projection of the filling layer 15 on the plane where the foam adhesive layer 11 is located is located within the area where the foam adhesive layer 11 is located, and the surface of the filling layer 15 away from the foam adhesive layer 11 is at most flush with the surface of the metal layer 12 away from the foam adhesive layer 11. In this way, through the design of the filling layer 15, the bonding effect of the edges of the laminated layers of the inward retraction design can be further improved, thereby extending the service life of the heat dissipation film 10.

Since the surface of the filling layer 15 away from the foam adhesive layer 11 is at most flush with the surface of the metal layer 12 away from the foam adhesive layer 11, that is, the filling layer 15 covers the area on the foam adhesive layer 11 that is not covered by the metal layer 12, and the thickness of the filling layer 15 is less than or equal to the thickness of the metal layer 12.

When the filling layer 15 is arranged on the side of the foam adhesive layer 11 towards the metal layer 12, due to the limitation of the glue coating process, in order to avoid the coated glue overflowing along the edge of the foam adhesive layer 11 and/or overflowing to the surface of the metal layer 12 away from the foam adhesive layer 11, at least part of the edge of the metal layer 12 has a certain amount of inward retraction. That is, in some embodiments, the distance between at least part of the edge of the orthographic projection of the metal layer 12 and the edge of the foam adhesive layer 11 is greater than or equal to 0.35 mm. That is, when the distance between at least part of the edge of the orthographic projection of the metal layer 12 and the edge of the foam adhesive layer 11 is greater than or equal to 0.35 mm, the heat dissipation film 10 includes a filling layer 15 located on the side of the foam adhesive layer 11 close to the metal layer 12. Of course, with the improvement of the glue coating process, the distance can be further reduced, that is, the above distance value of 0.35 mm is only an example and is not limited.

In the case where the filling layer 15 is arranged on the side of the foam adhesive layer 11 towards the metal layer 12, for example, as shown in FIG. 15, the heat dissipation film 10 includes a foam adhesive layer 11 and a metal layer 12. The corner edge of the metal layer 12 is greater than or equal to 1 mm inwardly contracted compared with the corner edge of the foam adhesive layer 11. At this time, when the filling layer 15 is made on the foam adhesive layer 11, the distance d1 between the glue coating point and the edge of the foam adhesive layer 11 is greater than or equal to 0.5 mm, and the distance d2 between the glue coating point and the edge of the metal layer 12 is less than or equal to 0.5 mm. For example, as shown in

FIG. 16, the heat dissipation film 10 includes an adhesive layer 111, a foam layer 112 and a metal layer 12. The inward retracted amount of the corner edge of the metal layer 12 relative to the corner edge of the foam layer 112, and the inward retracted amount of the corner edge of the foam layer 112 relative to the corner edge of the adhesive layer 111 are both greater than or equal to 0.96 mm. At this time, the distance d1 between the glue coating point on the adhesive layer 111 and the edge of the adhesive layer 111 is greater than or equal to 0.5 mm, and the distance d1 between the glue coating point on the foam layer 112 and the edge of the metal layer 12 is less than or equal to 0.5 mm. Still for example, as shown in FIG. 17, as for the adhesive layer 111, the foam layer 112, the intermediate laminated layer 13 and the metal layer 12, the inward retracted amount of the corner edge of the metal layer 12 relative to the corner edge of the intermediate laminated layer 13, and the inward retracted amount of the corner edge of the foam layer 112 relative to the corner edge of the adhesive layer 111 are both greater than or equal to 0.96 mm, and the edge of the intermediate laminated layer 13 is aligned with the edge of the foam layer 112. At this time, due to the thick thickness of the foam layer 112 and the intermediate laminated layer 13, the distance d1 between the glue coating point on the adhesive layer 111 and the edge of the adhesive layer 111 is greater than or equal to 0.6 mm, and the distance d2 between the glue coating point on the foam layer 112 and the edge of the metal layer 12 is less than or equal to 0.6 mm.

It should be noted that when applying glue on the foam adhesive layer 11, combined with the above-mentioned situation that the corner O of the metal layer 12 at the end of the notch 121 is an acute angle or an obtuse angle, relative to the situation that the corner O is an obtuse angle, when the corner O is an acute angle, it is convenient for the glue to flow back at the end of the notch 121, so as to reduce the probability of the glue overflowing the edge of the foam adhesive layer 11.

Further, as shown in FIG. 13 or FIG. 14, the heat dissipation film 10 further includes a release protective film 14. The release protective film 14 is located on the side of the metal layer 12 away from the foam adhesive layer 11, and the orthographic projection of the filling layer 15 on the foam adhesive layer 11 and the orthographic projection of the metal layer 12 on the foam adhesive layer 11 are both located within the orthographic projection of the release protective film 14 on the foam adhesive layer 11.

In this way, through the design of the release protective film 14, not only can the heat dissipation film 10 be protected, but also when the heat dissipation film 10 is pressed onto the display substrate by the roller, the contact area between the roller and the heat dissipation film 10 can be increased, thereby ensuring that the heat dissipation film 10 is adhered to the display substrate, and avoiding false adherence phenomenon in local areas. The material of the release protective film 14 can be PET.

The embodiment of the present disclosure provides a display module. The display module includes a display substrate and the heat dissipation film 10 described in the above embodiment. The display substrate has a display surface and a non-display surface, and the foam adhesive layer 11 included in the heat dissipation film 10 is attached to the non-display surface of the display substrate.

Combined with the heat dissipation film 10 described in the above embodiment, a certain yield can be guaranteed, and the service life can be extended, so that for the display module using the heat dissipation film 10, effective heat dissipation of the display substrate can be achieved, and the display effect of the display module can be guaranteed.

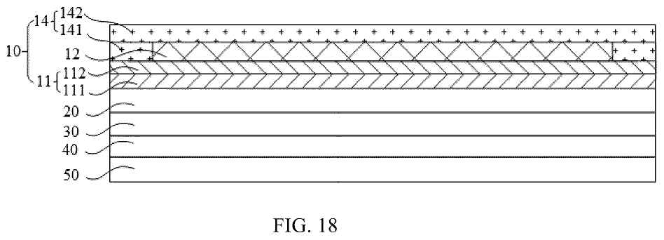

For example, as shown in FIG. 18, the display module includes a heat dissipation film 10, and a pixel panel 20, a polarizer 30, a transparent adhesive film 40 (e.g., a thermally cured optical clear adhesive TOCA) and a transparent cover plate 50 (e.g., a glass cover plate) sequentially laminated on the foam adhesive layer 11 of the heat dissipation film 10.

The embodiment of the present disclosure also provides a display device, which includes the display module described in the above embodiment. The display device can be a device with display function such as a mobile phone, a laptop computer, a tablet computer, a television, a display, a digital photo frame, a navigator, a touch-screen display all-in-one machine, etc.

Combined with the heat dissipation film 10 produced as described in the above embodiment, the display effect of the display module can be guaranteed, and then for the display device using the display module, the display effect of the display device can be guaranteed.

After considering the specification and practicing the present disclosure, those skilled in the art will easily think of other embodiments of the present disclosure. The present application is intended to cover any modification, use or adaptive change of the present disclosure, which follows the general principles of the present disclosure and includes common knowledge or conventional technical means in the technical field not disclosed in the present disclosure. It is intended that the specification and embodiments be considered as examples only, with a true scope and spirit of the disclosure being indicated by the following claims.

1. A heat dissipation film, comprising:
a foam adhesive layer; and
a metal layer, laminated on a side of the foam adhesive layer, wherein an orthographic projection of the metal layer on a plane where the foam adhesive layer is located is located within a region where the foam adhesive layer is located, and at least part of an edge of the orthographic projection of the metal layer is located inside an edge of the foam adhesive layer.

2. The heat dissipation film according to claim 1, wherein the foam adhesive layer comprises an adhesive layer and a foam layer;
the foam layer is located between the adhesive layer and the metal layer, an orthographic projection of the foam layer on a plane where the adhesive layer is located is located within a region where the adhesive layer is located, and at least part of an edge of the orthographic projection of the foam layer is located inside an edge of the adhesive layer; and
an orthographic projection of the metal layer on the adhesive layer is located within the orthographic projection of the foam layer on the adhesive layer, and at least part of an edge of the orthographic projection of the metal layer is located inside an edge of the orthographic projection of the foam layer.

3. The heat dissipation film according to claim 1, wherein the heat dissipation film further comprises an intermediate laminated layer;
the intermediate laminated layer is located between the foam adhesive layer and the metal layer, an orthographic projection of the intermediate laminated layer on the plane where the foam adhesive layer is located is located within the foam adhesive layer, and at least part of an edge of the orthographic projection of the intermediate laminated layer is located inside the edge of the foam adhesive layer; and
the orthographic projection of the metal layer on the foam adhesive layer is located within the orthographic projection of the intermediate laminated layer on the foam adhesive layer, and at least part of the edge of the orthographic projection of the metal layer is located inside an edge of the orthographic projection of the intermediate laminated layer.

4. The heat dissipation film according to claim 3, wherein the intermediate laminated layer comprises a plurality of intermediate laminated sub-layers;
two adjacent intermediate laminated sub-layers comprise a first intermediate laminated sub-layer close to the metal layer and a second intermediate laminated sub-layer away from the metal layer;
an orthographic projection of the first intermediate laminated sub-layer on the foam adhesive layer is located within an orthographic projection of the second intermediate laminated sub-layer on the foam adhesive layer, and at least part of an edge of the orthographic projection of the first intermediate laminated sub-layer is located inside an edge of the orthographic projection of the second intermediate laminated sub-layer.

5. The heat dissipation film according to claim 1, wherein the heat dissipation film is rectangular, and all of four corners of the metal layer have notches.

6. The heat dissipation film according to claim 5, wherein the corner of the metal layer comprises a first sub-notch extending in a row direction and a second sub-notch extending in a column direction, and a first end of the first sub-notch is communicated with a first end of the second sub-notch.

7. The heat dissipation film according to claim 6, wherein a corner of an edge of the metal layer at the second end of the first sub-notch is an acute angle.

8. The heat dissipation film according to claim 1, wherein the heat dissipation film further comprises a filling layer;
the filling layer is located on a side of the foam adhesive layer close to the metal layer, an orthographic projection of the filling layer on the plane where the foam adhesive layer is located is located within the region where the foam adhesive layer is located, and a surface of the filling layer away from the foam adhesive layer is at most flush with a surface of the metal layer away from the foam adhesive layer.

9. The heat dissipation film according to claim 8, wherein a distance between at least part of the edge of the orthographic projection of the metal layer and the edge of the foam adhesive layer is greater than or equal to 0.35 mm.

10. A display module, comprising a display substrate and a heat dissipation film, wherein the heat dissipation film comprises:
a foam adhesive layer; and
a metal layer, laminated on a side of the foam adhesive layer, wherein an orthographic projection of the metal layer on a plane where the foam adhesive layer is located is located within a region where the foam adhesive layer is located, and at least part of an edge of the orthographic projection of the metal layer is located inside an edge of the foam adhesive layer,
wherein the display substrate has a display surface and a non-display surface, and the foam adhesive layer comprised in the heat dissipation film is attached to the non-display surface of the display substrate.

11. A display device, comprising the display module according to claim 10.

12. The display module according to claim 10, wherein the foam adhesive layer comprises an adhesive layer and a foam layer;
the foam layer is located between the adhesive layer and the metal layer, an orthographic projection of the foam layer on a plane where the adhesive layer is located is located within a region where the adhesive layer is located, and at least part of an edge of the orthographic projection of the foam layer is located inside an edge of the adhesive layer; and
an orthographic projection of the metal layer on the adhesive layer is located within the orthographic projection of the foam layer on the adhesive layer, and at least part of an edge of the orthographic projection of the metal layer is located inside an edge of the orthographic projection of the foam layer.

13. The display module according to claim 10, wherein the heat dissipation film further comprises an intermediate laminated layer;
the intermediate laminated layer is located between the foam adhesive layer and the metal layer, an orthographic projection of the intermediate laminated layer on the plane where the foam adhesive layer is located is located within the foam adhesive layer, and at least part of an edge of the orthographic projection of the intermediate laminated layer is located inside the edge of the foam adhesive layer; and
the orthographic projection of the metal layer on the foam adhesive layer is located within the orthographic projection of the intermediate laminated layer on the foam adhesive layer, and at least part of the edge of the orthographic projection of the metal layer is located inside an edge of the orthographic projection of the intermediate laminated layer.

14. The display module according to claim 13, wherein the intermediate laminated layer comprises a plurality of intermediate laminated sub-layers;
two adjacent intermediate laminated sub-layers comprise a first intermediate laminated sub-layer close to the metal layer and a second intermediate laminated sub-layer away from the metal layer;
an orthographic projection of the first intermediate laminated sub-layer on the foam adhesive layer is located within an orthographic projection of the second intermediate laminated sub-layer on the foam adhesive layer, and at least part of an edge of the orthographic projection of the first intermediate laminated sub-layer is located inside an edge of the orthographic projection of the second intermediate laminated sub-layer.

15. The display module according to claim 10, wherein the heat dissipation film is rectangular, and all of four corners of the metal layer have notches.

16. The display module according to claim 15, wherein the corner of the metal layer comprises a first sub-notch extending in a row direction and a second sub-notch extending in a column direction, and a first end of the first sub-notch is communicated with a first end of the second sub-notch.

17. The display module according to claim 16, wherein a corner of an edge of the metal layer at the second end of the first sub-notch is an acute angle.

18. The display module according to claim 10, wherein the heat dissipation film further comprises a filling layer;
the filling layer is located on a side of the foam adhesive layer close to the metal layer, an orthographic projection of the filling layer on the plane where the foam adhesive layer is located is located within the region where the foam adhesive layer is located, and a surface of the filling layer away from the foam adhesive layer is at most flush with a surface of the metal layer away from the foam adhesive layer.

19. The display module according to claim 18, wherein a distance between at least part of the edge of the orthographic projection of the metal layer and the edge of the foam adhesive layer is greater than or equal to 0.35 mm.
